(19) United States
(12) Patent Application Publication
(10) Pub. No.: US 2007/0100086 A1
(43) Pub. Date: May 3, 2007

(54) Method of fabricating a three-dimensional nanostructure

(76) Inventors: Jae Min Hong, Seoul (KR); Won Il Son, Seoul (KR); Il Doo Kim, Seoul (KR)

Correspondence Address: JONES DAY, 222 EAST 41ST ST, NEW YORK, NY, 10017, US

(21) Appl. No.: 11/322,877

(22) Filed: Dec. 29, 2005

(30) Foreign Application Priority Data
Oct. 28, 2005 (KR) 10-2005-0102342

(51) Int. Cl. C23C 16/40; C08G 61/02; H01L 21/00; C23C 16/00

(52) U.S. Cl. 525/416; 427/250; 427/255.19; 438/800; 977/857

(57) ABSTRACT

There is provided a rapid and reliable method of fabricating a three-dimensional organic/inorganic nanostructure of a well-arranged shape wherein tubes or fibers of several nanometer to several micrometer size have horizontal and vertical orientations. The method of the present invention comprises the following steps: A) forming a tube- or fiber-type structure of an organic or inorganic nanometer/micrometer size by an interfacial polymerization method or interfacial reaction method; and B) obtaining the organic/inorganic composite three-dimensional nanostructure.

### FIELD OF THE INVENTION

The present invention relates to a method of fabricating a three-dimensional nanostructure, which is capable of maximizing a surface area of the nanostructure, and an array thereof. More specifically, the present invention is directed to a method of fabricating a three-dimensional nanostructure, which is capable of maximizing a surface area per unit area of a polymer or metal.

### BACKGROUND OF THE INVENTION

As consumers are increasingly drawn to more integrated and smaller electric devices, nanostructure materials and methods of manufacturing the same have been actively studied and researched. A method of making a polymer nanotube wherein an organic monomer becomes a micelle in an aqueous solution is advantageous since the procedure for implementing such method is fairly simple [see Adv. Mater. 15, No. 24, 2088 (2003)]. However, the above method is not suitable for mass production and produces a nanotube in which its length is not identical to its diameter.

Moreover, chemical vapor deposition (CVD) is a method of forming a nanostructure while depositing a monomer on a specimen under high vacuum [see Nano Letters, 1 (11), 631, 2001]. However, the CVD method is disadvantageous in that high temperature and high vacuum must be maintained while the process for manufacturing the nanotube is complex.

Also, there exists a method of preparing a nanoparticle by sol-gel process, which uses a nano-sized metal or inorganic oxide such as SiO, TiO₂ and the like [see Langmuir; (Communication); 2004; 20(7); 2523-2526]. There further exists a method of making a nano-sized metal particle by sputtering or spray pyrolysis process, which uses a porous metal [see J. Catal. 2003, 220, 35-43].

Although such methods can be used for manufacturing a wire, tube or particle on a nano-scale, it is not possible to manufacture an organic/inorganic three-dimensional nanostructure having a systematic arrangement suitable for fabricating electric devices.

Recently, in order to overcome such disadvantage, a template method using a plate having pores of an uniform size has been suggested as a method of fabricating a tube or fiber shape of several nanometer to several tens micrometer size [Science 1994, 266, 1961]. The template method is a method of manufacturing the nanotube or nanowire by the following steps: preparing a mixture solution of a monomer, a solvent and a dopant; making a metal electrode such as gold, silver, etc. on either side of the porous nanosubstance; and carrying out an electrical polymerization in said solution. The metal nanotube or nanowire can be manufactured by electroplating a metal salt in an aqueous solution using the same method.

However, since the template method uses a very limited reaction, which is applicable only for certain materials or an etching process, the template method is not suitable for use as a general method of fabricating a nanostructure.

### SUMMARY OF THE INVENTION

The object of the present invention is to provide a method of fabricating various types of three-dimensional organic/inorganic nanotube or nanofiber in a rapid and reliable manner.

During investigating a method for fabricating a well arranged three-dimensional nanostructure array, the present inventors have found that the three-dimensional nanoarray could be manufactured rapidly and reliably by using an interfacial synthesis method and evaporation, wherein the nanoarray has the structure of several tens nanometers to several tens millimeter size capable of maximizing the surface area per unit area.

Thus, the present invention is directed to a rapid and reliable method for fabricating three-dimensional organic/inorganic nanostructure of a well-arranged shape wherein tubes or fibers of several nanometer to several micrometer size have horizontal and vertical orientations.

Specifically, the method of fabricating the three-dimensional nanostructure composite of the present invention comprises the following steps:

A) forming a tube- or fiber-type structure of an organic or inorganic nanometer/micrometer size by an interfacial polymerization method or interfacial reaction method; and

B) obtaining the organic/inorganic composite three-dimensional nanostructure.

### BRIEF DESCRIPTION OF DRAWINGS

The above and other objects and features of the present invention will become apparent from the following description of the preferred examples given in conjunction with the accompanying drawings:

FIG. 1 is a schematic diagram showing a three-dimensional nanostructure of the present invention.

FIGS. 2a to 2e show a manufacturing process of a three-dimensional nanostructure using an interfacial synthesis method according to Example 1 of the present invention.

FIGS. 3a and 3b are scanning electron microscope photographs of a three-dimensional nanostructure having a diameter of 100 nm and fabricated in Example 1.

FIGS. 4a and 4b are scanning electron microscope photographs of a three-dimensional nanostructure having a diameter of 600 nm and fabricated in Example 2.

FIGS. 5a and 5b are scanning electron microscope photographs of a three-dimensional nanostructure having a diameter of 1000 nm and fabricated in Example 3.

FIGS. 6a and 6b are scanning electron microscope photographs of a three-dimensional silver nanofiber having a diameter of 200 nm and fabricated in Example 4.

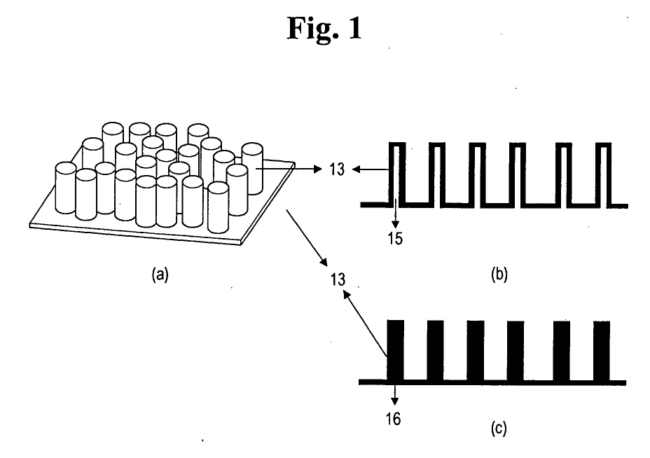

### DETAILED DESCRIPTION OF THE PRESENT INVENTION

The present invention provides a rapid and reliable method of fabricating a three-dimensional organic/inorganic nanotube or nanofiber of a well-arranged shape wherein the tubes or fibers of several nanometer to several micrometer size have horizontal and vertical orientations.

More specifically, the fabricating method of the present invention comprises the following steps:

A) i) mounting, on an oxidizing agent as an initiator or an aqueous monomer initiator solution, a porous polymer membrane having a diameter of several nanometers to several tens micrometers, forming a polymer in the polymer membrane by pouring a monomer solution in an organic solvent thereon to thereby diffuse the monomer at an interface of the aqueous phase and the organic solvent phase that are not intermixed, and forming a three-dimensional nanostructure array by removing the porous polymer membrane after polymerization, or

ii) mounting said porous polymer membrane on an inorganic substance or an aqueous metal salt solution and forming a metal structure in the porous polymer membrane by pouring a metal salt-reducing agent solution in an organic solvent thereon to thereby reduce the metal ion at an interface that is not intermixed, and

B) forming a three-dimensional nanostructure composite by coating metal or inorganic oxide on the three-dimensional nanostructure array or metal structure formed in step A).

The polymer membrane that can be used as the porous polymer membrane in said step A) includes, without limitation, any polymer membranes wherein the upper portion and lower portion of the polymer membrane are interconnected via pores, such as a separation membrane known as Track-etched membrane, for example, a polycarbonate separation membrane (GE Osmonics) or a polyethylene separation membrane used as an isolation membrane of a secondary battery and so on. Further, various combinations of the monomer and the water-soluble initiator for monomer polymerization can be used, and any polymerization reaction capable of carrying out the interface polymerization can be used in the present invention. The representative examples of the monomer/initiator combination include pyrrole monomer and iron chloride, and methylmethacrylate and potassium sulfate, etc.

Said step A) is a process of forming the organic or inorganic nanotube or nanofiber. The organic polymers that can be applied in the present invention include, without limitation, polycarbonate, polydimethylphenylene oxide, polysulfone, polyimide, polypyrrole as a conductive polymer, polyaniline, natural rubber, silicone polymer, poly(1-trimethylsilyl-1-propyne), polyphenylene oxide and polyethylene terephthalate, and mixture and copolymer thereof.

The examples of the metal salt used in said step A) include, without limitation, gold sulfate, gold cyanide, nickel phosphate, nickel sulfate and copper sulfate, etc., which are the salts of the coated metal ion.

Moreover, the exemplified inorganic substances include, without limitation, an inorganic substance such as a porous titania, silica, zirconia, zinc oxide (ZnO), tin oxide (SnO₂), iron oxide (Fe₂O₃), alumina and carbon, glass, metal such as SUS (stainless steel), silver, and mixture thereof. Further, said inorganic substance can be used as a mixture with one or more of said organic polymer.

Said step B) is a process for forming the organic/inorganic composite nanostructure. The three-dimensional nanotube or nanofiber manufactured in said step A) can be used as a template to produce many types of organic/inorganic nanotube. By using a physical chemical vapor deposition, an atomic layer deposition (ALD), a molecular beam epitaxy, a thermal or electron beam evaporation, a pulsed laser deposition (PLD), sputtering or spray pyrolysis of porous metal, casting, spin coating, sol-gel method, monomer evaporization, interfacial polymerization, LangmuirBlodgett method, electro/electroless plating, the metal or inorganic oxide such as SiO, TiO₂ and Al₂O₃ can be coated, thereby producing the composite having the three-dimensional nanostructure.

The surface area per unit area can be varied depending on the used template, and the physiochemical properties can be changed according to the properties of the used polymer or inorganic substance. Herein, the coated metal membrane includes Pt, Au, Ag, Al, Cr, Mo, Ti, Sn, Cu and the like, which can be deposited via the atomic layer deposition (ALD), molecular beam epitaxy, thermal or electron beam evaporation, etc.

The three-dimensional organic template can be removed by heating at 200 to 400° C. Through these procedures, a thin metal film of 3D structure can be obtained and used as a catalyst of a functional ceramic film and a lower electrode. Further, the inorganic oxides include red zirconium titanate [(Pb,Zr)TiO₃], BaTiO₃, (Ba,Sr)TiO₃, bismuth zinc niobate (Bi_{1.5}Zn_{1.0}Nb_{1.5}O₇) and calcium kappa titanate (CaCu₃Ti₄O₁₂), etc., which have high dielectric constant (high-K). As they are deposited on the 3D metal structure, the exponential increase of capacitance value can be accomplished due to the large area.

In addition, other materials such as zinc oxide (ZnO), tin oxide (SnO₂), titania (TiO₂), tungsten oxide (WO₃), calcium kappa titanate (CaCu₃Ti₄O₁₂) and barium titanate (BaTiO₃) are deposited on the 3D metal structure, which can increase the area/volume ratio sharply, thereby generating excellent sensor properties. The functional ceramics are limited to the examples indicated above.

Such three-dimensional organic structure can be formed directly on a patterned electrode, for example, interdigital capacitor structure (IDC structure). The porous ceramic film having the 3D structure on the EDC structure can be obtained by directly depositing the sensor materials (e.g., TiO₂, ZnO, SnO₂ and WO₃) on the 3D organic structure/IDC structure at a low temperature where the organic structure is subjected to a process such as ALD and then removing the 3D organic structure by heating at a high temperature.

Such porous TiO₂, ZnO, SnO₂ or WO₃ ceramic film can better improve the sensor properties due to gas diffusion and the reaction area increase. Moreover, since the film has more grain boundary per unit area, it can be applied for a varistor through the use of calcium kappa titanate (CaCu₃Ti₄O₁₂) or barium titanate (BaTiO₃), which is a material displaying excellent grain boundary property.

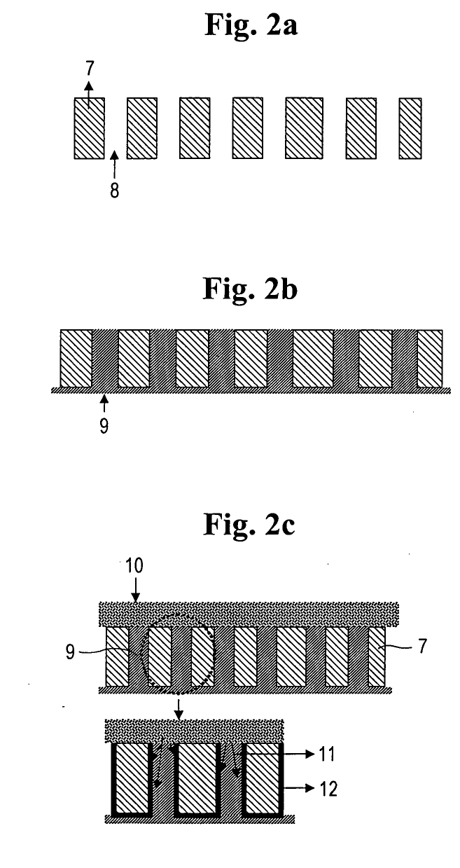

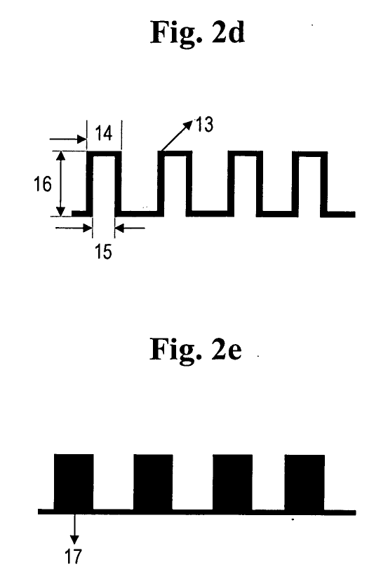

FIGS. 2a to 2e show a manufacturing process of three-dimensional nanostructure, specifically three-dimensional polymer nanotube, using the interfacial polymerization method according to one embodiment of the present invention.

Referring to FIG. 2, a porous polymer membrane 7 of a diameter of several nanometers to several tens micrometers having pores 8 is placed carefully on a water-soluble oxidizing agent 9 as in FIG. 2b. The water-soluble oxidizing agent 9 fills the pores 8 via capillary phenomenon. Thereafter, a monomer is dissolved in an organic solvent and the resulting solution 10 is poured slowly on the membrane as in FIG. 2c.

The monomer diffuses slowly through the oxidizing agent at an interface of the aqueous phase 9 and the organic solvent phase 10 that are not intermixed as shown as 11 in FIG. 2c. The polymer of the monomer 12 is formed on the polymer membrane 7. After polymerization, the resultant is washed during a predetermined period. Thereafter, the porous polymer membrane 7 used for the polymerization is removed through the use of a solvent, which results in the formation of a three-dimensional nanotube array 13 having a structure wherein a head portion of the tube is closed and the opposite portion thereof is open.

In FIG. 2d, the length 16 and outer diameter 14 of the nanotube can be controlled by the used polymer membrane 7. The inner diameter 15 of the nanotube depends on the reaction time and temperature, and the concentration of the oxidizing agent 9 and the monomer. Furthermore, if the reaction time is increased, it is possible to manufacture the nanofiber array 17 wherein the inner diameter 15 is completely filled as shown in FIG. 2e.

Though the shape or size of the three-dimensional nanostructure is not specifically limited in the present invention, the structure can be processed in the form of tube-type, hollow fiber-type, plate-type, sphere and sheet-type, etc. depending on its intended use. It can also be fabricated as the shape having several nanometer to several tens micrometer size according to the diameter and thickness of the used plate.

According to one embodiment of the present invention, it is possible to fabricate the three-dimensional nanostructure of tube shape having a size of several nanometers to several tens micrometers and having one side thereof closed, which is capable of maximizing the surface area per unit area of the nanotube in a level of several tens to several thousands times. Such manufactured nanostructure can be applied to various fields such as optical device, electric device, separation membrane, biomaterials, drug delivery, etc.

The method of manufacturing high performance nano-separation membrane according to the present invention will be explained in detail by the following examples with reference to the accompanying drawings. However, these examples are not intended to limit the present invention.

### EXAMPLE 1

A polycarbonate Track-etched membrane having pores (diameter: 100 nm) supplied by GE Osmonics, which is used as a porous polymer membrane, was placed on 0.2M of an aqueous solution of FeCl₃, a water-soluble oxidizing agent, as shown in FIG. 2b. The water-soluble oxidizing agent filled the pores via capillary phenomenon. Then, a pyrrole monomer solution in 0.2M of n-hexane was poured thereon as shown in FIG. 2c.

The pyrrole monomer and the oxidizing agent, which is a polymerization reaction initiator, were reacted at an interface of the aqueous phase and the organic solvent phase that were not intermixed, by which the polypyrrole (hereinafter referred to “PPy”) was formed inside the porous polymer membrane.

After polymerization for about 10 minutes, the resultant was washed with methanol and ultra-pure water. Thereafter, the polymer membrane used for the polymerization was removed through the use of methyl chloride in order to obtain a three-dimensional nanotube array having a structure wherein a head portion of the tube is closed and the opposite portion thereof is open.

Gold and nickel metal were plated on the fabricated polypyrrole nanotube array by electroless plating method. In addition to such plating, a metal film such as aluminium, gold and platinum, etc. was deposited on the polypyrrole nanotube array by CVD method or plasma coating method.

The electroless metal plating is composed of a pretreatment process including sensitization and activation, etc. and a plating process. The electroless gold plating was carried out in the following manner.

The membrane was washed with distilled water for 5 minutes and treated with a sensitization solution made with 0.026M SnCl2 and 0.07M trifluoroacetic acid for 45 minutes. After the washing process, the sensitization-treated membrane was treated with 0.029M of an ammoniacal silver nitrate solution as an activation solution for 2 minutes and then washed with distilled water. Finally, the membrane was impregnated in an aqueous solution of metal salt, which was previously prepared, and then plated at 5° C. The used aqueous solution of metal salt was prepared by dissolving 7.9×10⁻³M Na₃Au(SO₃)₂, 0.127M sodium sulfite and 0.625M formaldehyde in water.

The electroless silver plating was carried out as follows: The membrane was washed with methanol for 5 minutes and then treated with a solution consisting of 0.026M SnCl₂ and 0.07M trifluoroacetic acid for 30 minutes. Thereafter, the membrane was washed with methanol and treated with 160 mg/ml of Rochelle salt for 5 minutes. The membrane was washed with a deionized water and subject to a plating reaction by impregnating the membrane in a silver nitrate solution (20 ng/ml) including Rochelle salt at a room temperature.

The electroless nickel plating was carried out in the following manner. The membrane was treated with a solution made with 0.026M SnCl₂ and 0.07M trifluoroacetic acid for 10 minutes and impregnated in an ammoniacal silver nitrate solution for 5 minutes. Thereafter, the membrane was impregnated in 7.05×10⁻⁴M palladium chloride for 5 minutes and finally treated with 0.1 M sodium hypophosphite for 15 minutes. The electroless nickel plating was effected at a temperature of 30 to 60° C. by using an aqueous solution of metal salt composed of 30 g/l nickel sulfate, 50 g/l sodium acetate and 10 g/l sodium hypophosphite.

The electroless copper plating was carried out as set forth below. The membrane was washed with methanol for 5 minutes and treated a solution composed of 0.026M SnCl₂ and 0.07M trifluoroacetic acid for 10 minutes. Then, the membrane was washed with methanol and impregnated in 7.05×10⁻⁴M palladium chloride for 5 minutes. The membrane was washed with methanol again and treated with 5 wt % of formaldehyde for 10 minutes. The copper plating was effected by using an aqueous metal salt solution composed of 20 g/l copper sulfate, 17.5 ml formaldehyde, 43 g/l Rochelle salt and 21 g/l sodium hydroxide at a reaction temperature of 25 to 60° C.

Further, the tube array was coated with the inorganic oxide such as titania and silica, etc. by a vacuum deposition method, thereby forming the three-dimensional nanostructure having a composite structure of polymer/metal/ceramics.

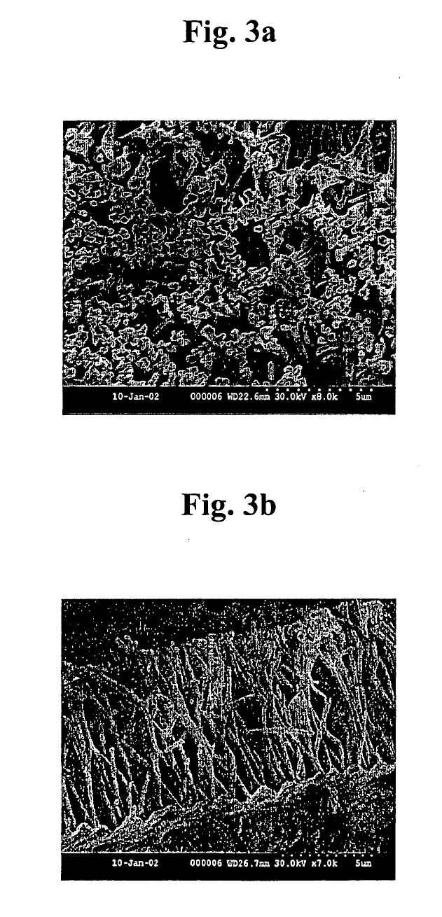

The scamming electron microscope photograph of the manufactured three-dimensional PPy nanotube was shown in FIG. 3. FIG. 3a is a scanning electron microscope photograph of a surface of the fabricated PPy nanotube having an outer diameter of 100 nm. FIG. 3b is a cross-section photograph of the nanotube.

From each of the cross-section photographs of the fabricated nanostructure, it can be noted that the length and diameter of the PPy nanotube are uniform.

### EXAMPLE 2

A three-dimensional nanostructure was prepared in the same way as in Example 1 except that the three-dimensional nanotube-type structure with an outer diameter of 600 nm and a thickness of 100 nm was formed through using the porous polymer membrane having a pore size of 600 nm.

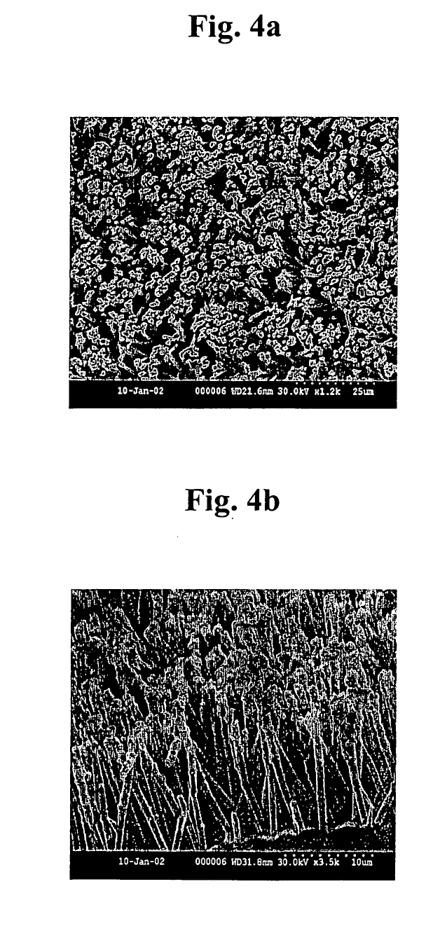

FIGS. 4a and 4b are scanning electron microscope photographs of a surface and cross-section of the three-dimensional nanostructure, which is fabricated in Example 2. From each of the cross-section of the fabricated nanostructure, it can be noted that the length and diameter of the PPy nanotube are uniform.

### EXAMPLE 3

A three-dimensional nanostructure was prepared in the same way as in Example 1 except that the three-dimensional nanotube-type structure with an outer diameter of 1000 nm and a thickness of 200 nm was formed by using the porous polymer membrane having a pore size of 1000 nm.

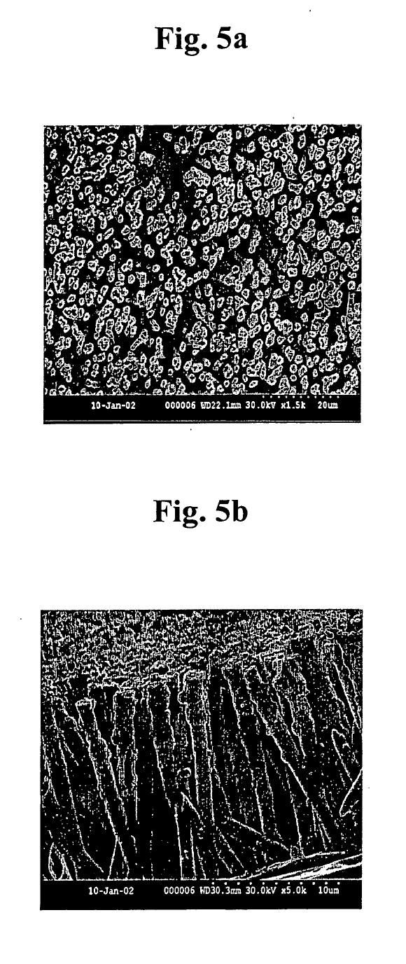

FIGS. 5a and 5b are scanning electron microscope photographs of a surface and cross-section of the three-dimensional nanostructure, which is fabricated in Example 3. From each of the cross-section of the fabricated nanostructure, it can be noted that the length and diameter of the PPy nanotube are uniform.

### EXAMPLE 4

Each of the silver, gold and copper nanofiber having a diameter of 200 nm was prepared in the same way as in Example 1 except that the electroless plating process was performed using silver nitrate, gold sulfate and copper sulfate as a water-soluble metal salt, respectively (instead as the water-soluble oxidizing agent).

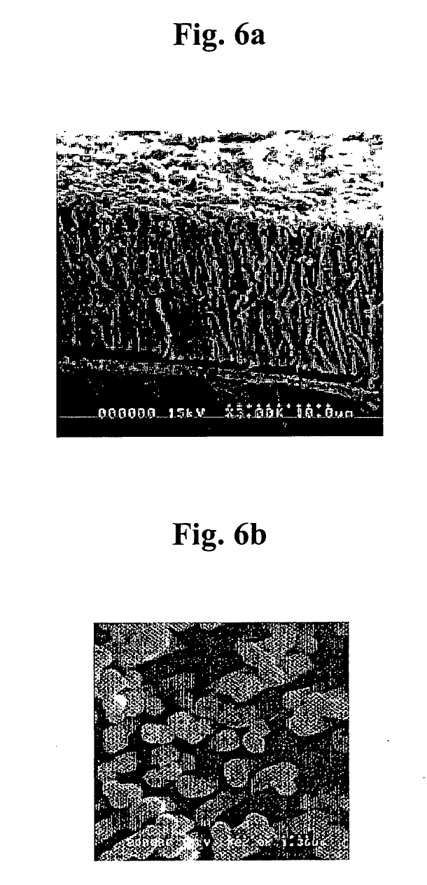

FIGS. 6a and 6b are scanning electron microscope photographs of the three-dimensional silver nanofiber, which is fabricated in Example 4. Since the structure of the metal nanofiber has a very great specific surface area, it can be applied for an electrode of an electrical reaction using a large area and sensor electrode, etc.

According to the present invention, there is provided a method of fabricating a three-dimensional nanostructure array in a rapid and reliable manner. Especially, the present invention provides a simple method for forming a well-arranged array having a three-dimensional nanofiber or tube shape. The three-dimensional nanostructure manufactured by the method can maximize the surface area per unit area of a polymer or metal. Thus, it can be used in constituting an apparatus and system such as nano-separation membrane, magnetic recording apparatus, nano-condenser, separation membrane, biomaterials, drug delivery, etc.

While the present invention has been shown and described with respect to a preferred embodiment, those skilled in the art will recognize that various changes and modifications may be made without departing from the scope of the invention as defined in the appended claims.

What is claimed is:

1. A method of fabricating a three-dimensional nanostructure composite, comprising the steps of:
A) i) mounting, on an oxidizing agent as an initiator or an aqueous monomer initiator solution, a porous polymer membrane having a diameter of several nanometers to several tens micrometers, forming a polymer in the polymer membrane by pouring a monomer solution in an organic solvent thereon to thereby diffuse the monomer at an interface of the aqueous phase and the organic solvent phase that are not intermixed, and forming a three-dimensional nanostructure array by removing the porous polymer membrane after polymerization, or
ii) mounting said porous polymer membrane on an inorganic substance or an aqueous metal salt solution and forming a metal structure in the porous polymer membrane by pouring a metal salt-reducing agent solution in an organic solvent thereon to thereby reduce the metal ion at an interface that is not intermixed, and
B) forming a three-dimensional nanostructure composite by coating metal or inorganic oxide on the three-dimensional nanostructure array or metal structure formed in step A).

2. The method according to claim 1, wherein the three-dimensional nanostructure array in i) of step A) is composed of an organic polymer, metal or inorganic substance, or a mixture or composite thereof.

3. The method according to claim 2, wherein the organic polymer is selected from a group consisting of polycarbonate, polydimethylphenylene oxide, polysulfone, polyimide, polypyrrole, polyaniline, natural rubber, silicone polymer, poly(1-trimethylsilyl-1-propyne), polyphenylene oxide and polyethylene terephthalate, and mixture and copolymer thereof.

4. The method according to claim 2, wherein the metal salt used in ii) of step A) is selected from a group consisting of gold sulfate, gold cyanide, nickel phosphate, nickel sulfate and copper sulfate.

5. The method according to claim 2, wherein the inorganic substance used in ii) of step A) is selected from a group consisting of a porous titania, silica, zirconia, zinc oxide (ZnO), tin oxide (SnO₂), iron oxide (Fe₂O₃), alumina, carbon, glass, stainless steel and silver, and a mixture thereof.

6. The method according to claim 1, wherein the metal in step B) is Pt, Au, Ag, Al, Cr, Mo, Ti, Sn or Cu.

7. The method according to claim 1, wherein the inorganic oxide in step B) is selected from a group consisting of a porous titania, silica, zirconia, zinc oxide (ZnO), tin oxide (SnO₂), magnesium oxide (MgO), tungsten oxide (WO₃), barium titanate (BaTiO₃), red zirconium titanate [(Pb,Zr)TiO₃], calcium kappa titanate (CaCu₃Ti₄O₁₂), bismuth zinc niobate (Bi_{1.5}Zn_{1.0}Nb_{1.5}O₇), alumina and carbon, glass, stainless steel and silver, and a mixture thereof.
